(19) United States
(12) Patent Application Publication
(10) Pub. No.: US 2025/0291176 A1
(43) Pub. Date: Sep. 18, 2025

(54) MIRROR ARRANGEMENT WITH COOLED MIRROR ELEMENTS AND LITHOGRAPHY SYSTEM

(71) Applicant: Carl Zeiss SMT GmbH, Oberkochen (DE)

(72) Inventors: Hermann BIEG, Huettlingen (DE); Stefan WALZ, Schwaebisch Gmuend (DE); Markus HOLZ, Aalen (DE); Thomas WOLFSTEINER, Aalen (DE); Andreas FROMMEYER, Schwaebisch Gmuend (DE); Andreas-Josef GRIMM, Rainau (DE)

(21) Appl. No.: 19/226,233

(22) Filed: Jun. 3, 2025

Related U.S. Application Data
(63) Continuation of application No. PCT/EP2023/084043, filed on Dec. 4, 2023.

(30) Foreign Application Priority Data
Dec. 6, 2022 (DE) 10 2022 213 142.8

(51) Int. Cl. G02B 26/08; B81B 7/00; G03F 7/00

(52) U.S. Cl. CPC G02B 26/0858; B81B 7/0093; G02B 26/0841; G03F 7/702; B81B 2201/042; B81B 2203/0338; B81B 2207/053

(57) ABSTRACT

A mirror arrangement, for example for a lithography system, comprises: a plurality of mirror elements, for example in the form of MEMS mirror modules, for reflecting radiation; a plurality of carrier elements, each having a head region for accommodating one of the mirror elements; and a mount arrangement comprising insert openings, which are designed to accommodate a respective seat portion of the carrier elements. The plurality of carrier elements are accommodated with the seat portions in the insert openings in the mount arrangement. Each carrier element comprises a channel device for guiding a coolant, which comprises an inlet for the coolant and an outlet for the coolant.

### CROSS-REFERENCE TO RELATED APPLICATIONS

The present application is a continuation of, and claims benefit under 35 USC 120 to, international application No. PCT/EP2023/084043, filed Dec. 4, 2023, which claims benefit under 35 USC 119 of German Application No. 10 2022 213 142.8, filed Dec. 6, 2022. The entire disclosure of each of these applications is incorporated by reference herein.

### FIELD

The disclosure relates to a mirror arrangement, such as for a lithography system, comprising: a plurality of mirror elements, such as in the form of MEMS mirror modules, for reflecting radiation; a plurality of carrier elements, each having a head region for accommodating one of the mirror elements; and a mount arrangement, which comprises insert openings, which are designed to accommodate a respective seat portion of the carrier elements, wherein the plurality of carrier elements are accommodated with the seat portions in the insert openings in the mount arrangement. The disclosure also relates to a lithography system having at least one such mirror arrangement. The lithography system can be a lithography apparatus for exposing a wafer or some other optical arrangement used for lithography, such as an inspection system, for example for inspecting masks, wafers, (mirror) elements or the like that are used in lithography. The lithography system can be embodied for use in EUV lithography, such as in the form of an EUV lithography apparatus which is used to produce semiconductor components and operated with short wavelength radiation, so-called EUV radiation, at an operating wavelength between approximately 5 nanometers (nm) and approximately 30 nm.

### BACKGROUND

In lithography systems, specifically in EUV lithography systems, heat is produced, among other things, due to the absorption of EUV radiation, heating of optical elements e.g. in the form of mirrors, due to electrical power loss during the movement of actuators, etc. The heat produced when operating a lithography system can be dissipated by cooling the components of the lithography system.

The components to be cooled may be, for example, mirror elements in the form of micromirror arrays, such as in the form of microelectromechanical mirror modules (“MEMS mirror modules”). A MEMS mirror module has a plurality of micromirrors in a grid arrangement, which are typically actuable or tiltable about at least one, generally two axes and which are mounted on a carrier, usually in the form of a substrate. The micromirrors are relatively small components in each case (size of the respective mirror surface approximately one square millimeter (mm²), for example) and are often controlled or actuated with the aid of logic elements and micromechanical structures in chip format. The MEMS mirror modules themselves can be arranged in the form of a grid arrangement, wherein a mirror arrangement may comprise several hundred mirror elements in the form of MEMS mirror modules.

Such MEMS mirror modules have relatively high demands with respect to cooling. This is partially because of the high thermal loads due to the incident radiation such as in the case of an EUV lithography system having a high source power of the EUV light source, and due to the electronics for driving the MEMS mirrors, which can create heat. Another reason is that the MEMS mirror modules themselves can be temperature-sensitive. The temperature sensitivity can concern not only the reflective coating which is applied to the micromirrors for the case that EUV radiation is intended to be reflected, but also the electronics or drives for the micromirrors. For example, there are MEMS concepts with piezo drives in which the piezo material is heated to above approximately 70° C. because otherwise its piezoelectric properties could be lost and the piezo drive may no longer function. This demand is considerable and it is believed that it cannot be fulfilled by any of the currently known cooling concepts for micro-mirrors, of which several will be described below.

DE 10 2014 219 770 A1 describes a mirror arrangement designed as is described in the introductory part. A channel device for guiding a heat carrier medium is formed in the mount arrangement of the mirror arrangement in the region of the seat portion of a respective carrier element. A local channel system (heat pipe), which can be formed in the carrier element, is embodied to assist the heat transfer from the region of the head portion to the region of the seat portion, in conjunction with a phase change of a heat carrier medium introduced into this local channel system of the carrier element.

DE 10 2016 211 040 A1 describes a projection exposure apparatus comprising a carrier body in which at least partially conical components of the projection exposure apparatus are accommodated. The carrier body comprises conical receptacle openings and at least one separate insert element for improving the heat transition between the components and the carrier body is arranged in the region between the conical portions of the components and an inner joining surface of the receptacle openings. The conical portions may be, for example, facet lower parts of mirror facets of a facet mirror.

DE 10 2015 223 793 A1 describes a projection exposure apparatus including at least one mirror arrangement with a plurality of mirror elements, wherein the mirror elements are arranged at least in part in an insert opening in a mirror mount. The mirror arrangement is designed such that it counteracts a heat-related bending of the mirror mount.

DE 10 2014 203 144 A1 describes an assembly of an optical system, comprising an element and at least one temperature control device for controlling the temperature of this element, wherein the temperature control device has a coolant inside a closed circuit having at least one pipe-type portion, wherein this coolant is transportable in the pipe-type portion away from the element or toward the element by performing a two-phase transition, and wherein heating equipment for interrupting the coolant transport by heating the coolant is provided.

DE 10 2013 205 214 B4 describes micromechanical or microelectromechanical equipment for a projection exposure apparatus, comprising at least one micromechanical or microelectromechanical element and a temperature-control device comprising a gas supply mechanism and a gas aspiration mechanism. The at least one micromechanical or microelectromechanical element is encapsulated in a housing which has a gas supply line and a gas removal line and at least one window for the working light of the projection exposure apparatus. The equipment can be a multi-mirror arrangement having a multiplicity of electromechanical micromirrors.

DE 10 2009 054 869 A1 describes a mirror for guiding a beam. The mirror comprises a main body and a coating of a reflection surface of the main body which increases the reflectivity of the mirror. A heat dissipation device is used to dissipate heat deposited in the coating. The heat dissipation device comprises at least one Peltier element, and the coating is applied directly to the Peltier element.

### SUMMARY

The disclosure seeks to provide a mirror arrangement which enables efficient cooling of mirror elements, for example in order to prevent a temperature threshold of the mirror elements from being exceeded. The disclosure also seeks to provide a lithography system, such as a lithography apparatus, having at least one such mirror arrangement.

In a first aspect, the disclosure provides a mirror arrangement, in which the carrier elements each have a channel device for guiding a coolant, which has an inlet for a coolant and an outlet for the coolant. The mirror arrangement, such as for a lithography system, can comprises: a plurality of mirror elements, such as in the form of MEMS mirror modules, for reflecting radiation; a plurality of carrier elements, each having a head region for accommodating one of the mirror elements; and a mount arrangement, which comprises insert openings, which are designed to accommodate a respective seat portion of the carrier elements, wherein the plurality of carrier elements are accommodated with the seat portions in the insert openings in the mount arrangement.

It has been found that a relatively efficient cooling of or dissipation of heat from the mirror elements involves a heat path from the heat source (the mirror elements) to the coolant that is reduced or kept as short as possible. This can be achieved by direct cooling of the carrier elements, in which the carrier elements themselves have a channel device to which the coolant is fed and from which it is discharged. By contrast, in the mirror arrangement described in DE 10 2014 219 770 A1, the coolant is not fed into the carrier elements and discharged therefrom. Rather, it is proposed here to implement in the carrier elements a local (closed) cooling system in the form of a heat pipe. This and further measures, for example the use of materials having good thermal conductivity (e.g. copper), the enlargement of the channel cross section for reducing the thermal resistance (which is generally limited by the available installation space), the prevention or improvement of contact resistances (e.g. by the use of contact promoters, thermal pastes, etc.), and the lowering of the reference temperature or of the temperature of the coolant (e.g. to less than 22° C.), have, in terms of their performance for the cooling of the mirror elements, proved to be insufficient to produce a sufficient heat flow, for example in the MEMS mirror modules described further above, to maintain the temperature of the mirror elements below, for example, 70° C. As was described further above, the piezo elements provided in the MEMS mirror modules may lose their piezoelectric properties when this temperature threshold is exceeded. It is understood that the direct cooling of the mirror elements with the aid of the carrier elements, as proposed herein, can also be used in mirror elements which are not MEMS mirror modules or which are based on electrostatic drives. Likewise, the prevention of a temperature threshold from being exceeded may be desirable for different reasons, for example to prevent excessive heating of the reflective coating of the micromirrors.

In one embodiment, the channel device is designed for feeding the coolant into the head region and for discharging the coolant from the head region of a respective carrier element. For effective cooling, it has proven desirable for the coolant to be guided into the head regions of the carrier elements and to flow through them. For example, it is desirable for the coolant to be directed in the respective head region, at which a respective carrier element typically projects over a respective insert opening, to just below the mirror elements in order to cool them. In this way, the heat path can be significantly reduced compared to the cooling concepts that have been known so far, and the temperature at the mirror elements can thus be decreased.

In one embodiment, the channel devices have in a respective head region for guiding the coolant at least one meander-shaped channel and/or a plurality of channels for guiding the coolant in parallel. It is desirable for an end face of the head region of the carrier elements, which is adjoined by a respective mirror element or at which a respective mirror element is attached, to be cooled as uniformly as possible over its entire surface area. This can typically be accomplished if the channel device has meander-shaped channels or if the channel device has a plurality of channels for guiding the coolant in parallel.

In the design of the channel device, attention should generally be paid to the fact that dynamic disturbances (so-called flow induced vibrations) which are as small as reasonably possible are produced during the guidance of the coolant. Flow induced vibrations are typically due to eddy formation (turbulence) when the coolant flows through the channels of the channel device. Eddy formation can be reduced with a suitable design of the geometry of the channels. For example, rounded edges can be used for this purpose when the flow direction of the coolant changes, as already occurs in the case of a meander. Sharp edges or corners should generally be avoided in the guidance of the fluid.

The channel device can have in the head region of a respective carrier element channels for guiding the coolant, which extend over a proportion of more than 50%, such as more than 70%, for example more than 90%, of an end face of the head region. As has been described further above, it is desirable for the heat exchange surface for the coolant at the head region or at the end face to be as large as reasonably possible. It is likewise desirable for the channels to extend at the smallest reasonably possible distance from the end face of the head region, which distance may be, for example, approximately 1 millimeter (mm) or less. By guiding the coolant as close to the heat introduction as is reasonably possible, a minimum thermal resistance can be achieved (largest possible heat exchange surface and greater thermal transfer coefficient).

In an embodiment, the mount arrangement comprises a channel system which has a feed opening for feeding the coolant to the inlet and a discharge opening for discharging the coolant from the outlet of the channel device of a respective carrier element. Using the channel system, it is possible to efficiently dissipate heat from the carrier element carrying a respective mirror element. The temperature of the coolant guided through the channel system can be adjusted such that it substantially corresponds to the target temperature of the mirror arrangement. The channel system in the mount arrangement can be designed, for example, in the manner described in DE 10 2014 219 770 A1, which is incorporated in its entirety in this application by reference.

As is described in DE 10 2014 219 770 A1, it is possible that the channel system formed in the mount arrangement is designed such that it is used to achieve parallel cooling of a plurality of carrier elements. This is desirable because, in contrast to serial cooling, with parallel cooling the coolant can be fed at the same starting temperature (e.g. 22° C.) to each carrier element and consequently to each mirror element.

For the case described here, where feeding and discharging the coolant takes place via the mount arrangement, sealing between a respective carrier element and the mount arrangement can be used. The carrier elements which are accommodated in the insert openings are typically releasably connected to the mount arrangement. In contrast to the mirror arrangement as described in DE 10 2014 219 770 A1, it is generally desirable in the mirror arrangement described here, in which feeding and discharge of the coolant takes place via the mount arrangement, to open the cooling circuit during the replacement of the carrier elements or the mirror elements. However, in the mirror arrangement described here, the performance of the cooling of the mirror elements is significantly increased compared to DE 10 2014 219 770 A1.

In one development of this embodiment, the inlet and the outlet of the channel device are formed at the seat portion of a respective carrier element, and the seat portion is accommodated in the insert opening in a sealing manner in the region of the inlet and the outlet of the channel device. In this case, the feeding and discharge of the coolant can take place at the seat portion of the carrier element, which may be, for example, conical or cylindrical. For radial sealing, a radial sealing device, for example in the form of O-rings or the like, can be used, for example.

In one development of this embodiment, the inlet and the outlet of the channel device of a respective carrier element each open into an intermediate space, for example a ring space, which is sealed by seals which extend between the seat portion of the carrier element and the insert opening. The seals can be, for example, O-rings or the like. The two intermediate spaces into which the inlet and the outlet of the channel device of the respective carrier element open can be separated from each other by an O-ring or another type of seal.

In one further development, the feed opening for feeding the coolant opens into a first intermediate space, for example into a first ring space, into which the inlet of the channel device opens, and the discharge opening for discharging the coolant opens into a second intermediate space, for example a second ring space, into which the outlet of the channel device opens. In this way, the radial seal between the carrier element and the mount arrangement described further above can be implemented.

In principle, it is possible that the channel device in a respective carrier element comprises two or more channel systems, which are separated from each other in a fluid-tight manner and which each have a separate inlet and a separate outlet. However, this can involve an independent sealing of the channel systems and is generally not desirable because of the relatively small installation space available.

In one alternative embodiment, the inlet and the outlet of the channel device are formed on a side of the head region of the respective carrier element facing the end face of the mount arrangement, laterally offset with respect to the insert opening. In the present embodiment, the inlet and the outlet of the carrier element are not located on the seat portion, which dips into the insert opening, but are arranged on the head region opposite the end face of the mount arrangement. The head region of a respective carrier element in this case can project over the insert opening or over the mount arrangement and extends laterally next to the insert opening, which in this case may be comparatively narrow, because no coolant needs to be fed or discharged through the seat portion. The inlet and the outlet of the channel device can likewise be arranged laterally offset with respect to the insert opening and can be sealed off in a fluid-tight manner from the environment using an axial seal or sealing arrangement.

In one development, the inlet and the outlet of the channel device each open into an intermediate space, which is formed between the side of the head region facing the end face of the mount arrangement and the end face of the mount arrangement, wherein the respective intermediate space is sealed off from the environment using a sealing arrangement. In this case, an axial seal can be used to seal off the two intermediate spaces from the environment.

The feed opening for feeding the coolant can open into a first intermediate space, into which the inlet of the channel device opens, and the discharge opening for discharging the coolant can open into a second intermediate space, into which the outlet of the channel device opens. For sealing the two intermediate spaces, in principle two separated seals can be used. However, it is generally desirable for a sealing arrangement to be used which is formed of a single (molded) seal. Such a seal has two openings which each form, if the carrier element is accommodated in the insert opening, one of the two intermediate spaces through which the cooling fluid can flow. The seal can have a through opening, which is adjacent to the seat portion of the carrier element or surrounds the seat portion in the shape of a ring. The location of the seal relative to the carrier element and consequently also the location of the openings for the passage of the coolant can be specified in this way.

In an alternative embodiment, the inlet and the outlet of the channel device of a respective carrier element are separated from the mount arrangement in a fluid-tight manner. In this embodiment, the inlet and the outlet of the channel device of a respective carrier element are not fluidically connected to the mount arrangement. The mount arrangement in this case can serve merely as a holder for the mirror elements and does not have a channel system for feeding the coolant to the inlet of a respective carrier element or for discharging the coolant from the outlet of a respective carrier element. Therefore, no heat exchange can take place in this embodiment between the coolant within the cooling channels of the cooling system of the mount arrangement and the material of the mount arrangement. In the embodiment described here, the thermal deformations of the mount arrangement can therefore be decreased. For feeding the coolant to the inlet and for discharging the coolant from the outlet of the cooling device of a respective carrier element, there are several possibilities in this embodiment. Generally, the inlet and the outlet are formed on a side of the carrier element facing away from the head region, but this is not absolutely necessary. The inlet and the outlet are typically located here in a region of the carrier element which is accessible from the lower side of the mount arrangement.

In one development of this embodiment, the inlet and the outlet of the channel device are formed on a fixing portion of a respective carrier element which projects over the insert opening, wherein the inlet and the outlet of the channel device can be connected in a fluid-tight manner to a channel system of a heatsink arranged adjacent to the mount arrangement.

In the embodiment described here, the respective inlet and the respective outlet of a carrier element may be connected via lines, for example via hose connections, to external cooling equipment or to an external cooling circuit. Alternatively, it is possible for the inlet and the outlet to be directly connected to a channel system of a heatsink arranged adjacent to the mount arrangement. The connection can be realized using a sealing arrangement via which the inlet and the outlet of a respective carrier element are connected in a fluid-tight manner to the channel system of the heatsink. For example, the sealing arrangement can be designed as an axial or radial seal. With a suitable design of the sealing arrangement, for example in the form of an adapter, it may be possible for a respective carrier element or mirror element to be replaced without coolant emerging in the process. The channel system of the heatsink can be designed for allowing parallel flow through the channel devices of the carrier elements. By guiding the coolant in a spatially separate heatsink provided in addition to the mount arrangement, the thermal deformations of the mount arrangement can be decreased.

In one embodiment, the carrier element has at least one fixing portion for fixing the carrier element in the insert opening in the mount arrangement, and the mirror arrangement can be configured to connect the inlet and the outlet of the channel device in a fluid-tight manner to the channel system of the mount arrangement or to the channel system of the heatsink when fixing the carrier element in the insert opening.

For fixing the carrier elements to the mount arrangement, more specifically in the insert opening, a fixing portion of a respective carrier element can be used, via which a holding force securing the carrier element in the mount arrangement is introduced into the carrier element. The fixing portion can be designed, for example, as a threaded portion on which a nut is located which generates the holding force in the tightened state (fixed position). The holding force generated by the nut can be conducted into the mount arrangement by the inclusion of the spring, for example. It is also possible for a push-out mechanism to be placed in the region of the fixing portion, which mechanism enables the carrier element to be pushed out of the mount arrangement “from below.” The fixing portion can project over the insert opening. Alternatively or additionally it is possible for one or more fixing sections of the carrier element to be formed, with a lateral offset with respect to the insert opening, on the side of the head region lying opposite the end face of the mount arrangement. For feeding and discharging the coolant, it is desirable if the fixing section projects over the insert opening and the inlet and the outlet are formed on the projecting fixing portion.

When fixing the carrier element to the fixing portion, for example by tightening the nut, described further above, which fixing portion is in the form of a threaded portion, a fluid-tight connection between the inlet and the outlet of the channel device of the carrier element to the channel system of the mount arrangement or the heatsink can be provided automatically when the carrier element is in a fixed position. As has been described further above, the inlet of the channel device in the fixed position of the carrier element can for this purpose open into an (intermediate) space, which is separated in a fluid-tight manner and into which the feed opening of the channel system also opens. The same applies to the outlet of the channel device and the discharge opening of the channel system. For the case that the channel system is formed in the mount arrangement, the application of the holding force can ensure or enhance the fluid-tight sealing of the respective (intermediate) space with respect to the environment by way of the contact pressure of the associated seal or sealing arrangement being increased. Even for the case that the inlet and the outlet are not connected in a fluid-tight manner to the mount arrangement, the inlet and the outlet can be “automatically” connected in a fluid-tight manner for example to the channel system of the heatsink described further above or possibly to a feed opening and a discharge opening of the lines of a cooling circuit or external cooling equipment when fixing the carrier element in the mount arrangement.

The coolant can be, for example, water, a water-containing mixture, glycol, a gas or a gas mixture or liquid CO₂, wherein in the latter case the phase transition from the liquid into the gas phase may be used.

In one embodiment, the carrier element can be made at least in the head region from a ceramic material having a coefficient of thermal expansion that deviates by less than 100% (i.e. a factor of two), such as less than 70%, from a coefficient of thermal expansion of a material of the mirror element which adjoins an end face of the head region. For the case that the mirror elements are MEMS mirror modules, it is desirable if the material of the carrier element at least in the head region is made from a material which has a similar coefficient of thermal expansion (CTE) to the MEMS micromirrors or the underlying substrate. In this way, thermal stresses, i.e. deformation and damage, can be avoided.

As has been described further above, a MEMS mirror module comprises a plurality of microelectromechanically actuable micromirrors, which are generally arranged in a grid arrangement (array). The respective micromirrors are individually actuable and can typically be tilted about at least one axis, typically about two axes. The number of micromirrors in a MEMS mirror module may vary; by way of example, 24×24 or 25×25 micromirrors, for example, can be arranged in a grid arrangement. A respective MEMS module typically also comprises logic elements and micromechanical structures in chip format, in order to control or actuate the micromirrors.

The MEMS modules or micromirrors themselves are typically made from silicon, the underlying substrate, which comprises the logic elements and actuators, is made from a multilayer ceramic printed circuit board (PCB), for example based on aluminum nitride, which has a very high thermal conductivity and a low coefficient of thermal expansion (in the order of less than 5 ppm/K at 20° C.).

A good material for the carrier element is therefore likewise a ceramic which exhibits high thermal conductivity and in addition has a similarly low coefficient of thermal expansion to the ceramic substrate of the MEMS mirror module. In addition, the material of the carrier element should make it possible to produce the channels in the cooling device in the simplest manner possible. Ceramic materials suitable for this purpose, which have a coefficient of thermal expansion in the order of a few ppm/K are, for example, aluminum oxide ceramics, which are optimized for dissipating heat. Aluminum oxide ceramics of this type are known from the prior art.

Alternatively, the carrier element can be produced at least in the head region from a material (e.g. copper, silicon, SiC, molybdenum alloys, tungsten alloys or stainless steel) having a coefficient of thermal expansion which significantly deviates from the coefficient of thermal expansion of the mirror element or the MEMS mirror module. In this case, the integration of thermal or mechanical decoupling between the material of the carrier element and the material of the mirror element can be desirable to avoid high thermal stresses in the component parts. Thermal decoupling can be realized for example by a joint or the like.

A further aspect of the disclosure relates to a lithography system, for example a lithography apparatus, comprising: at least one mirror arrangement, as is described further above, wherein the mirror arrangement can be arranged in an illumination system for illuminating a reticle. Such an illumination system may comprise for example two or more mirror arrangements, which each comprise a plurality of mirror elements which may be designed, for example, in the form of MEMS mirror modules and in the manner described further above.

Further features and aspects of the disclosure are evident from the following description of exemplary embodiments of the disclosure with reference to the figures of the drawing, which illustrate certain details of the disclosure, and from the claims. The individual features may be realized in one variant of the disclosure individually by themselves or in any desired combination.

### BRIEF DESCRIPTION OF THE DRAWINGS

Exemplary embodiments are illustrated in the schematic drawing and will be explained in the description below. In the figures:

FIG. 1 schematically shows in the meridional section a projection exposure apparatus for EUV projection lithography, having an illumination system having two facet mirrors;

FIG. 2 shows a perspective illustration of a mirror arrangement in the form of the first facet mirror of the illumination system of FIG. 1 having a plurality of mirror elements;

FIG. 3A shows a schematic sectional illustration of three mirror elements of the mirror arrangement of FIG. 2, which are mounted on carrier elements which have been inserted with a seat portion into the insert openings in a mount arrangement;

FIG. 3B shows a schematic illustration of a carrier element having, introduced therein, a channel device which has an inlet and an outlet for a coolant, which are formed on a seat portion of the carrier element;

FIG. 4 shows a schematic illustration of a head region of a carrier element having a plurality of channels through which a coolant can flow in parallel;

FIG. 5A shows a schematic illustration similar to FIG. 3A, in which the seat portion of the respective carrier element does not extend to a side of the mount arrangement facing away from the mirror elements;

FIG. 5B shows a schematic illustration similar to FIG. 3B, in which the inlet and the outlet for the coolant are formed at a head portion of the carrier element; and

FIGS. 6A-6B show schematic illustrations of a carrier element having, introduced therein, a channel device which has an inlet and an outlet for a coolant, which are not connected to the mount arrangement.

### DETAILED DESCRIPTION

In the following description of the drawings, the same or functionally identical structural parts are denoted by identical reference signs.

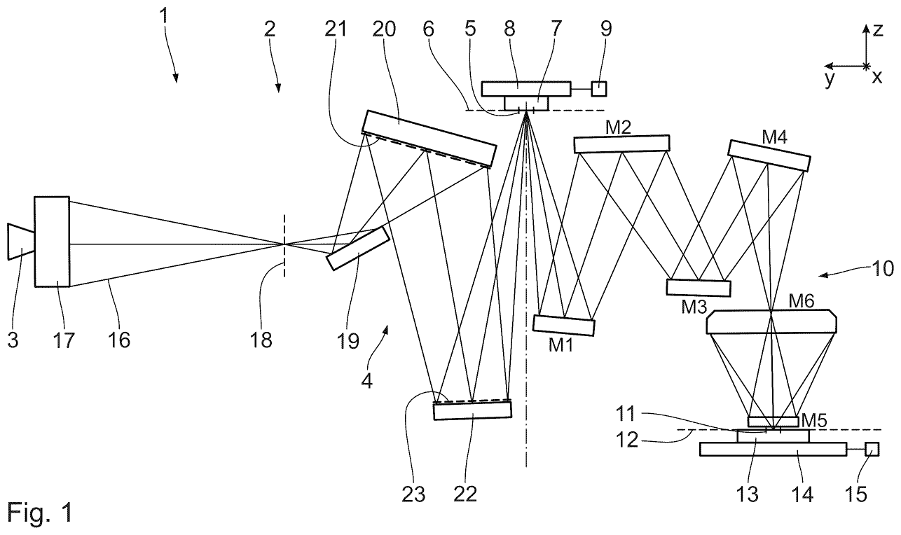

With reference to FIG. 1, the following text describes by way of example certain constituent parts of an optical arrangement for EUV lithography in the form of a microlithographic projection exposure apparatus 1 (EUV lithography apparatus). The description of the basic setup of the projection exposure apparatus 1 and of its constituent parts should not be understood to have a limiting effect.

One embodiment of an illumination system 2 of the projection exposure apparatus 1 has, in addition to a light or radiation source 3, an illumination optical unit 4 for illuminating an object field 5 in an object plane 6. In an alternative embodiment, the light source 3 may also be provided in the form of a module separate from the rest of the illumination system. In this case, the illumination system does not comprise the light source 3.

A reticle 7 arranged in the object field 5 is illuminated. The reticle 7 is held by a reticle holder 8. The reticle holder 8 is displaceable for example in a scanning direction using a reticle displacement drive 9.

FIG. 1 shows for illustration purposes a Cartesian xyz-coordinates system. The x-direction runs perpendicularly into the drawing plane. The y-direction runs horizontally, and the z-direction runs vertically. The scanning direction in FIG. 1 runs along the y-direction. The z-direction runs perpendicularly to the object plane 6.

The projection exposure apparatus 1 comprises a projection system 10. The projection system 10 is used to image the object field 5 into an image field 11 in an image plane 12. A structure on the reticle 7 is imaged on a light-sensitive layer of a wafer 13 arranged in the region of the image field 11 in the image plane 12. The wafer 13 is held by a wafer holder 14. The wafer holder 14 is displaceable for example in the y-direction using a wafer displacement drive 15. The displacement of the reticle 7 on the one hand using the reticle displacement drive 9 and of the wafer 13 on the other hand using the wafer displacement drive 15 may be synchronized.

The radiation source 3 is an EUV radiation source. The radiation source 3 emits for example EUV radiation 16, which is also referred to below as used radiation, illumination radiation or illumination light. The used radiation has for example a wavelength in the range of between 5 nm and 30 nm. The radiation source 3 can be a plasma source, for example an LPP (Laser Produced Plasma) source or a GDPP (Gas Discharge Produced Plasma) source. It can also be a synchrotron-based radiation source. The radiation source 3 can be a free electron laser (FEL).

The illumination radiation 16 emanating from the radiation source 3 is focused by a collector mirror 17. The collector mirror 17 can be a collector mirror with one or more ellipsoidal and/or hyperboloidal reflection surfaces. The illumination radiation 16 can be incident on the at least one reflection surface of the collector mirror 17 with grazing incidence (GI), i.e. at angles of incidence of greater than 45°, or with normal incidence (NI), i.e. at angles of incidence of less than 45°. The collector mirror 17 can be structured and/or coated, firstly, for optimizing its reflectivity for the used radiation and, secondly, for suppressing extraneous light.

Downstream of the collector mirror 17, the illumination radiation 16 propagates through an intermediate focus in an intermediate focal plane 18. The intermediate focal plane 18 can constitute a separation between a radiation source module, comprising the radiation source 3 and the collector mirror 17, and the illumination optical unit 4.

The exposure optical unit 4 comprises a deflection mirror 19 and, downstream thereof in the beam path, a first facet mirror 20. The deflection mirror 19 may be a plane deflection mirror or, alternatively, a mirror with a beam-influencing effect that goes beyond the pure deflection effect. Alternatively or additionally, the deflection mirror 19 may be in the form of a spectral filter, which separates a used light wavelength of the illumination radiation 16 from extraneous light of a different wavelength. The first facet mirror 20 comprises a multiplicity of individual first facets 21, which are also referred to below as field facets. FIG. 1 illustrates only some of these facets 21 by way of example. In the beam path of the illumination optical unit 4, a second facet mirror 22 is disposed downstream of the first facet mirror 20. The second facet mirror 22 comprises a plurality of second facets 23.

The illumination optical unit 4 thus forms a double-faceted system. This basic principle is also referred to as a fly's eye condenser (fly's eye integrator). The individual first facets 21 are imaged into the object field 5 using the second facet mirror 22. The second facet mirror 22 is the last beam-shaping mirror or actually the last mirror for the illumination radiation 16 in the beam path upstream of the object field 5. Alternatively, the illumination system 2 can be based on the principle of the specular reflector as is described, for example, in DE 10317667 A1, which is incorporated in its entirety in this application by reference.

The projection system 10 comprises a plurality of mirrors Mi, which are consecutively numbered in accordance with their arrangement in the beam path of the projection exposure apparatus 1.

In the example illustrated in FIG. 1, the projection system 10 comprises six mirrors M1 to M6. Alternatives with four, eight, ten, twelve or any other number of mirrors Mi are likewise possible. The penultimate mirror M5 and the last mirror M6 each have a passage opening for the illumination radiation 16. The projection system 10 is a doubly obscured optical unit. The projection optical unit 10 has an image-side numerical aperture which is greater than 0.4 or 0.5 and which can also be greater than 0.6 and which can be for example 0.7 or 0.75.

Just like the mirrors of the illumination optical unit 4, the mirrors Mi can have a highly reflective coating for the illumination radiation 16.

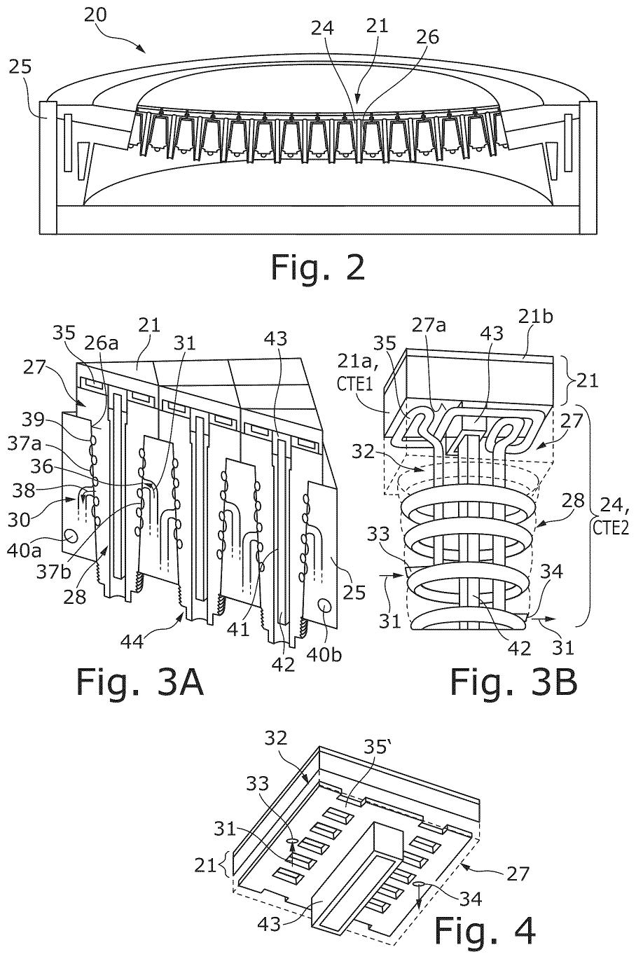

FIG. 2 shows the mirror arrangement in the form of the first facet mirror 20 of the illumination system 2 of FIG. 1 in a partial section. The mirror arrangement 20 has a plurality of mirror elements 21 which are arranged in close proximity, form a concave surface and are aligned with respect to an optical center. Each of the mirror elements 21 serves to reflect electromagnetic radiation, specifically EUV radiation 16, which is reflected from the first facet mirror 20 of the illumination system 2 to the facets 23 of the mirror arrangement 22 in the form of the second facet mirror. In the example shown, the mirror elements 21 are in the form of MEMS mirror modules. A respective MEMS mirror module has a number of micromirrors which are arranged in a grid (e.g., with 24×24 micromirrors) and which can be actuated, more precisely tilted, on an individual basis. A respective mirror element 21 in the form of a MEMS mirror module has logic elements and micromechanical structures in chip format for this purpose. The mirror elements 23 or the facets of the second facet mirror 22 are likewise designed as MEMS mirror modules.

The mirror arrangement 20 shown in FIG. 2 also comprises a plurality of carrier elements 24, which each carry one of the mirror elements 21. The mirror arrangement 20 also has a mount arrangement 25 which in the example shown comprises conical insert openings 26 designed to accommodate a respective one of the conical carrier elements 24. The mount arrangement 25 has a multi-part structure and moreover has mount shells put together in layered fashion. The carrier elements 24 each have a head region 27, shown in FIGS. 3A-3B, which projects over the insert opening 26 and on which a respective mirror element 21 is mounted. The carrier elements 24 dip with a seat portion 28 into the insert opening 26. Regarding details of the structure of the mirror arrangement 20, of how the carrier elements 24 are fastened to the mount arrangement 25 and the structure of the mount arrangement 25, reference is made to DE 10 2014 219 770 A1.

FIG. 3A shows the mirror arrangement 20 of FIG. 2 in a partial section with three mirror elements 21, the reflective surfaces or end faces of which have a square geometry in the example shown. It is understood that the mirror elements 21 may also have a different geometry. As likewise evident from FIG. 3A, the mirror elements 21 are arranged in a grid arrangement having a plurality of rows and columns. In order to cool the mirror elements 21, the mount arrangement 25 has a channel system 30, which is used to guide a coolant 31, cooling water in the example shown here. Alternatively, another coolant 31 could also be used, for example a water-containing mixture, glycol, a gas or gas mixture or (liquid) CO₂.

A respective carrier element 24 has a cooling device 32 shown in FIG. 3B in the form of a hollow structure, which has an inlet 33 for letting in the coolant 31 and an outlet 34 for letting out the coolant 31, which are formed in each case at the seat portion 28 of the carrier element 24. As is likewise shown in FIG. 3B, the channel device 32 is designed for feeding the coolant 31 into the head region 27 and for discharging the coolant 31 from the head region 27 of a respective carrier element 24, which is illustrated using dashes in FIG. 3B. In the example shown in FIG. 3B, the channel device 32 has exactly one continuous channel 35, which initially extends from the inlet 33 in the radial direction and then in the axial direction in order to guide the coolant 31 from the seat portion 28 into the head region 27 of the carrier element 24. In the head region 27 of the carrier element 24, the channel 35 is meander-shaped to ensure that the channel 35 extends over the largest possible proportion of a surface on an end face 27a of the head region 27 of the carrier element 24 which, in the example shown, is more than approximately 50% of the surface area of the end face 27a of the head region 27, and ideally more than 70% or more than 90%. The channel 35 then runs back in the axial direction from the head region 27 to the seat portion 28 of the carrier element 24 and then runs in the radial direction toward the outlet 34.

For feeding the coolant 31 to the inlet 33 of the carrier element 24, the channel system 30 of the mount arrangement 25 has a feed opening 36 shown in FIG. 3A. The feed opening 36 opens into a first ring space 37a, which is formed between a cutout in an inner wall 26a of the conical insert opening 26 and the carrier element 24. The inlet 33 of the channel device 32 of the carrier element 24 also opens into the first ring space 37a. Accordingly, a discharge opening 38 of the channel system 30 of the mount arrangement 25 opens into a second ring space 37b, which is formed between a further cutout in the inner wall 26a of the insert opening 26 and the carrier element 24. The two ring spaces 37a, 37b are sealed off from one another and from the environment using radial seals in the form of O-rings 39. The seals 39 extend for this purpose between the seat portion 28 of the carrier element 24 and the insert opening 26 for the carrier element 24. To accommodate the seals 30, ring-shaped grooves are disposed in the seat portion 28 of the carrier element 24.

The channel system 30 of the mount arrangement 25 has a number of feed openings 36 and discharge openings 38 that corresponds to the number of mirror elements 21. The channel system 30 of the mount arrangement 25 is designed to allow parallel flows through the channel devices 32 of the carrier elements 24 and for this purpose has a meander-shaped distribution channel 40a, to which the feed openings 36 are connected, and a meander-shaped collector channel 40b, to which the discharge openings 38 are connected. The distribution channel 40a and the collector channel 40b are indicated in FIG. 3A in the form of circles.

As can be seen in FIG. 3A, a respective carrier element 24 has a through channel 41 for passing connecting and control lines through the carrier element 24. The connecting and control lines in the example shown are mounted on a rod-shaped printed circuit board 42, which is plugged into a plug connector 43 of the MEMS mirror module 21, which is mounted on the carrier element 24, in order to control the actuators which are integrated there. The actuators in the example shown are piezo actuators, which should not exceed a threshold temperature of approximately 70° C., because they will otherwise lose their piezoelectric properties and the micromirrors of the MEMS mirror module 21 can no longer be actuated. Rather than piezo actuators, it is also possible to use other types of actuators, for example electrostatic drives. In addition to the temperature of the piezo actuators, the electronic components and the reflective coating of the micromirrors should not exceed a threshold temperature either.

As can be seen in FIG. 3B, a respective mirror element 21 in the form of a MEMS mirror module comprises a ceramic substrate 21a and, applied on the ceramic substrate 23a, a micromirror array 21b with a number of, for example, 24×24 micromirrors. The substrate 21a is made from a ceramic material in the form of aluminum nitride, which has a very high thermal conductivity and a low coefficient of thermal expansion CTE1 of approximately 5 ppm/K at 20° C. The carrier element 24 is likewise produced from a ceramic material in the form of aluminum oxide, which has a comparable coefficient of thermal expansion CTE2 of approximately 3 ppm/K. For the coefficient of thermal expansion CTE1 of the material of the carrier element 24 and the coefficient of thermal expansion CTE2 of the material of the substrate 21a, which adjoins an end face 27a of the head region 27 of the carrier element 24, the following applies: CTE1/CTE2=5/3=1.66. The coefficient of thermal expansion CTE2 of the material of the carrier element 24 therefore deviates by less than 70% from the coefficient of thermal expansion CTE2 of the substrate 21a of the mirror element 21.

The carrier element 24 can be connected to the mirror element 21 in different ways, for example by welding, soldering, adhesive bonding or by mechanical connection structures, by wedging or by a different joining method. The connection should enable surface-type contact between the end face 27a of the head region 27 of the carrier element 24 and the respective mirror element 21. For the case that the material of the carrier element 24 has a coefficient of thermal expansion CTE2 which differs greatly from the coefficient of thermal expansion CTE1 of the mirror element 21 or the substrate 21a, it may be desirable to realize mechanical decoupling of the carrier element 24 from the mirror element 21, for example by providing a joint or the like. In this way, thermal stresses and associated deformations and damage can be avoided.

As can likewise be seen in FIG. 3A, the carrier elements 24 have on the sides facing away from the mirror elements 21 a respective fixing portion 44, which is provided with a threaded portion. For example, a nut, which in the tightened state (fixed position) generates a holding force for the carrier element 24, can be located on the fixing portion. The holding force generated by the nut can be transferred into the mount arrangement 25 for example with the use of a spring.

FIG. 4 shows the head region 27 of the carrier element 24, which differs from the carrier element 24 shown in FIG. 3B in that the channel device 32 comprises, in place of a meander-shaped channel 35, a plurality of parallel channels 35′, 35″, which are used to guide the coolant 31. The coolant 31 in the example shown in FIG. 4 enters the head region 27 of the carrier element 24 at the inlet 33 and is initially distributed over six parallel first channels 35′, through which the coolant 31 flows in parallel. The coolant 35 is then guided around the plug connector 43 of the mirror element 32, which dips into the through channel of the carrier element 24 (not depicted in FIG. 4). The coolant 31 is then distributed over six second channels 35″ of the channel device 32, through which the coolant 31 flows in parallel, before the coolant 31 exits the carrier element 24 at the outlet 34.

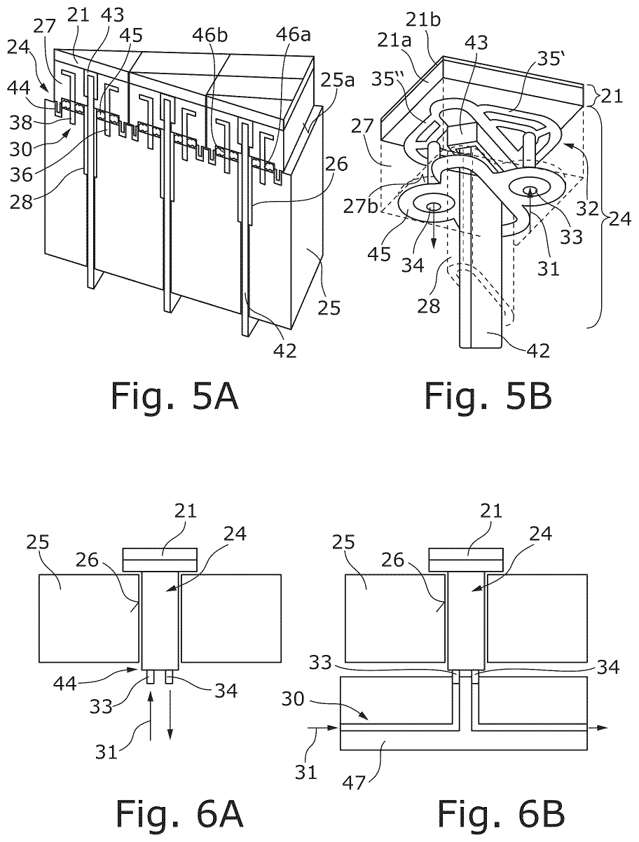

In contrast to the carrier element 24 shown in FIGS. 3A-3B, the inlet 33 and the outlet 34 in the carrier element 24 shown in FIG. 4 are mounted on the head region 27, more specifically on a lower side of the head region 27 facing away from the mirror elements 21. FIGS. 5A-5B likewise show carrier elements 24, in which the inlet 33 and the outlet 34 are formed at the side 27b of the head region 27 facing away from the mirror elements 21. As can be seen in FIGS. 5a,b, the head region 27 projects not only upward over a respective insert opening 26 of the mount arrangement 25, but also extends laterally next to the insert opening 26, with the result that the inlet 33 and the outlet 34 for the coolant 31 are arranged, with a lateral offset with respect to the insert opening 26, on the side 27b of the head region 27 facing away from the mirror element 21.

In order to connect the channel system 30 of the mount arrangement 25 in a fluid-tight manner to the inlet 33 and the outlet 34 of the head region 27 of the carrier element 24, the mirror arrangement 20 comprises a sealing arrangement, which seals in the axial direction and is designed as a molded seal 45 in the example shown. The molded seal 45 is located in its installation position between an end face 25a of the mount arrangement 25 facing the mirror elements 21 and the lower side 27b of the head region 27 of the respective carrier element 24. The molded seal 45 has a first opening, which, in its installation position, forms a first intermediate space 46a into which the feed opening 36 of the channel system 30 of the mount arrangement 25 opens in order to feed the coolant 31 to the inlet 33. The molded seal 45 has a second opening, which, in its installation position, forms a second intermediate space 46b, into which the discharge opening 38 of the channel system 30 of the mount arrangement 25 opens, in order to discharge the heated coolant 31 exiting from the outlet 34.

The carrier element 24 in the example shown has four fixing portions 44, which are each provided with a threaded portion. The fixing portions 44, of which FIG. 5A shows two, are arranged in the region of the corners of the head region 27 of the carrier element 24. Unlike the case in FIGS. 3A-3B, the fixing portions 44 in the example shown in FIGS. 5A-5B are mounted on the lower side 27b of the head region 27 of the carrier element 24 facing the mount arrangement 25. The fixing portions 44 project downward over the remaining head region 27 of the carrier element 24 and exert a holding force acting in the axial direction on the carrier element 24 by way of correspondingly shaped nuts. Due to the application of the holding force, the molded seal 45 is also compressed in the axial direction in order to enhance the sealing action thereof.

As can be seen in FIGS. 5A-5B, the seat portion 28 with which the carrier element 24 dips into the mount arrangement 25 has a significantly smaller cross section than the seat portion 28 of the carrier element 24 shown in FIGS. 3A-3B. This is due to the fact that no coolant 31 is guided in the seat portion 28 of the carrier element 24 of FIGS. 5A-5B. The seat portion 28 of the carrier element 24 extends in the axial direction only over approximately half the height of the mount arrangement 25, which is sufficient for the correct alignment of the carrier element 24 relative to the mount arrangement 25. The seat portion 28 in the example shown has a cylindrical geometry with an oval, non-radially symmetric cross section. This makes it possible to align the respective carrier element 24 in a desired rotational position during the insertion into the insert opening 26.

As can likewise be seen in FIG. 5B, the molded seal 45 has a third opening, through which extends the seat portion 28 of the carrier element 24. In the example shown in FIGS. 5A-5B, the rod-shaped printed circuit board 42 is plugged, as it is in FIGS. 3A-3B, into the plug connector 43 of the MEMS mirror module 21 mounted on the carrier element 24. The through channel 41 of the carrier element 24 is continued in a through opening of the mount arrangement 25 following the insert opening 26 in order to insert, and be able to make contact with, the rod-shaped printed circuit board 42 from the lower side of the mount arrangement 25.

As is shown in FIG. 5B, the coolant 31 flows, in the channel device 32 starting from the inlet 33, through the head region 27 initially in an axial channel and is guided therein into the immediate vicinity of the end face 27a of the head region 27 of the carrier element 24. Here, the coolant 31 is distributed over a plurality of channels 35 carrying parallel flows, before it is combined again to laterally flow around the plug connector 43. Next, the coolant 31 is distributed again over a plurality of channels 35″, which carry parallel flows, before the coolant 31 is guided via a further channel extending in the axial direction to the outlet 34 of the cooling device 32.

Both in the example shown in FIGS. 3A-3B and in the example shown in FIGS. 5A-5B, the channels 35, 35′, 35″ run in the immediate vicinity of the MEMS mirror module 21, more specifically of the lower side of the substrate 21a, to be precise typically at a distance of approximately 1 mm or less. In this way, the heat path from the heat source in the form of the mirror elements 32 to the coolant 31 can be minimized.

FIGS. 6A-6B each show a detail of a mirror arrangement 20, in which the mount arrangement 25 has no channel system for feeding and discharging the coolant 31 to and from the channel device 32 of the carrier element 34. The inlet 33 and the outlet 34 of the channel device 32 of the carrier element 24 (not depicted in FIGS. 6A-6B) are therefore not fluidically connected to the mount arrangement 25.

In the example shown in FIG. 6A, the coolant 31 is fed to the inlet 33, which is formed at a fixing portion 44 of the carrier element 24 projecting over the insert opening 26, via a feed line (not depicted) from an external cooling device and discharged via a discharge line (not depicted) by the outlet 34 and transported to the external cooling device. The outlet 34 is likewise formed at the fixing portion 44 of the carrier element 24 projecting over the insert opening 26.

In the example shown in FIG. 6B, arranged adjacent to the mount arrangement 25 is a heatsink 47 comprising a channel system 30, which is designed analogously to the channel system 30 of the mount arrangement 25, in order to feed the coolant 31 to the inlet 33 of the carrier element 24 and discharge it from the outlet 34 of the carrier element 24. Thermal deformations of the mount arrangement 25 can be reduced by guiding the coolant 31 in the additional heatsink 47. In this case, too, it can be desirable to seal off the inlet 33 and the outlet 34 using seals (not depicted). A radial and/or axial sealing concept can be used to this end. With a suitable design of the respective seals, for example in the manner of a suitable adapter or the like, it is possible for the carrier element 24 to be replaced, if appropriate, without the need to interrupt the transport of the coolant 31 for this purpose. For example, a fluid-tight connection between the inlet 33 and the outlet 34 and the channel system 30 of the heatsink 47 can be established when fixing the carrier element 24 in the mount arrangement 25.

It is understood that not only the first facet mirror 20, but also the second facet mirror 22 may be designed in the manner described further above. Mirror arrangements which are not part of the illumination system 2 or the lithography apparatus 1 can also be designed in the manner described further above in order to minimize the heat path to the coolant 31 as much as possible.

What is claimed is:

1. A mirror arrangement, comprising:
a plurality of MEMS mirror modules, each MEMs mirror module comprising a plurality of mirror elements configured to reflect radiation;
a plurality of carrier elements, each carrier element comprising a head region and a seat portion, each head region accommodating a corresponding one of the plurality of mirror elements;
a mount arrangement comprising insert openings, each insert opening accommodating a corresponding seat portion of one of the carrier elements,
wherein:
each carrier element comprises a channel configured to guide a coolant between an inlet of the channel and an outlet of the channel; and
one of the following holds:
the mount arrangement comprises a plurality of feed openings and a plurality of second openings, and for each channel: a corresponding feed opening in the mount arrangement is configured to provide the coolant to the inlet of the channel; and a corresponding discharge opening in the mount arrangement is configured to discharge the coolant from the outlet of the channel; or
for each channel, each of the inlet and the outlet is separated from the corresponding mount arrangement in a fluid-tight manner.

2. The mirror arrangement of 1, wherein, for each carrier element, its channel is configured to provide the coolant into its head region and to discharge the coolant from the head region.

3. The mirror arrangement of claim 2, wherein, within the head region of each carrier, the channel is meander-shaped.

4. The mirror arrangement of claim 2, wherein, for each carrier, its channel extends over more than 50% of a surface on an end face of its head region.

5. The mirror arrangement of claim 2, wherein, within the head region of each channel, the channel comprises a plurality of channels configured to guide the coolant in parallel.

6. The mirror arrangement of claim 2, wherein, for each carrier, the plurality of channels extend over more than 50% of a surface on an end face of its head region.

7. The mirror arrangement of claim 1, wherein:
the mount arrangement comprises a plurality of feed openings and a plurality of discharge openings; and
for each channel: a corresponding feed opening in the mount arrangement is configured to provide the coolant to the inlet of the channel; and a corresponding discharge opening in the mount arrangement is configured to discharge the coolant from the outlet of the channel.

8. The mirror arrangement of claim 7, wherein, for each channel:
the inlet and the outlet are at the seat portion; and
the seat portion is sealed in the corresponding insert opening in a region of the inlet and the outlet.

9. The mirror arrangement of claim 8, wherein, for each channel, the inlet opens into an intermediate space, and the outlet opens into the intermediate space.

10. The mirror arrangement of claim 8, wherein, for each channel, the inlet opens into a ring space, the outlet opens into the ring space, and the ring space is sealed by seals extending between the seat portion of the corresponding carrier element and the corresponding insert opening.

11. The mirror arrangement of claim 8, wherein, for each channel:
the corresponding feed opening opens into a first intermediate space into which the inlet of the channel opens; and
the corresponding discharge opening opens into a second intermediate space into which the outlet of the channel opens.

12. The mirror arrangement of claim 8, wherein, for each channel:
the corresponding feed opening opens into a first ring space into which the inlet of the channel opens; and
the corresponding discharge opening opens into a second ring space into which the outlet of the channel opens.

13. The mirror arrangement of claim 12, further comprising seals that seal the first and second ring spaces are sealed from each other.

14. The mirror arrangement of claim 7, wherein, for each channel, the inlet and the outlet are disposed, with a lateral offset relative to the insert opening, on a side of the head region of the corresponding carrier element facing an end face of the mount arrangement.

15. The mirror arrangement of claim 14, wherein, for each channel:
the inlet and the outlet each open into an intermediate space between the side of the head region facing the end face of the mount arrangement and the end face of the mount arrangement; and
the intermediate space is sealed from the environment by a sealing arrangement.

16. The mirror arrangement of claim 15, wherein for each channel:
the corresponding feed opening opens into a first intermediate space into which the inlet opens; and
the corresponding discharge opening opens into a second intermediate space into which the outlet opens.

17. The mirror arrangement of claim 1, wherein, for each channel, each of the inlet and the outlet is separated from the corresponding mount arrangement in a fluid-tight manner.

18. The mirror arrangement of claim 17, wherein, for each channel, the inlet and the outlet are disposed at a fixing portion of the corresponding carrier element.

19. The mirror arrangement of claim 1, wherein, for each carrier element, the carrier element comprises a fixing portion fixing the carrier element in the corresponding insert opening of the mount arrangement.

20. The mirror arrangement of claim 1, wherein, for each carrier element, the head region comprises a material having a coefficient of thermal expansion which deviates by less than 100% from a coefficient of thermal expansion of a material of the mirror element which adjoins an end face of the head region.

21. A apparatus, comprising:
an illumination system configured to illuminate an object,
wherein the illumination system comprises a mirror arrangement according to claim 1, and the apparatus if a lithography apparatus.
